(19) United States
(12) Patent Application Publication
(10) Pub. No.: US 2021/0208516 A1
(43) Pub. Date: Jul. 8, 2021

(54) RETICLE STAGE FOR PREVENTING HAZE CONTAMINATION AND EXPOSURE APPARATUS HAVING THE SAME

(71) Applicant: XIA TAI XIN SEMICONDUCTOR (QING DAO) LTD., Qingdao (CN)

(72) Inventors: JIYONG YOO, Singapore (SG); BYUNG-IN KWON, Singapore (SG); DAE-YOUP LEE, Singapore (SG)

(21) Appl. No.: 16/736,588

(22) Filed: Jan. 7, 2020

(51) Int. Cl. G03F 7/20

(52) U.S. Cl. CPC G03F 7/70741; G03F 7/70825; G03F 7/70758; G03F 7/70833; G03F 7/70775; G03F 7/70983

(57) ABSTRACT

A reticle stage for holding a reticle assembly is provided. The reticle assembly has a reticle and a pellicle covering the reticle. The reticle stage includes a reticle stage base, a reticle holder disposed on the reticle stage base and for holding the reticle assembly over the reticle stage base, and an electrostatic generator coupled to the reticle assembly. The electrostatic generator is configured to generate static electricity to the reticle assembly. The static electricity alternates between positive electricity and negative electricity.

### FIELD

The present disclosure generally relates to a reticle stage for preventing haze contamination and an exposure apparatus having the same. More specifically, the present disclosure relates to a reticle stage having an electrostatic generator that can prevent haze particles from contaminating the reticle.

### BACKGROUND

Integrated circuits are generally made by photolithographic processes that use reticles (or photomasks) and an associated light source to project a circuit image on the surface of a silicon wafer. Reticles are generally made from flat pieces of quartz or soda-lime glass coated with a metallic layer (e.g., a chromium layer) forming a pattern for an electronic circuit. A pellicle is typically used to seal the reticle, so as to isolate and protect the patterns of the reticle surface from particulate contamination and eliminate dust or other particles from the focal plane of the pattern. The reticle and the pellicle may be collectively called a reticle assembly. Contaminating particles may be caught between the reticle and the pellicle when the two are affixed together. The contaminating particles on the surface of the reticle and pellicle may cause the photolithographic pattern transmitted on the wafer to change, distort, alter, etc. from its intended design, ultimately impacting the quality of the semiconductor device manufactured. Referring to FIG. 1, a schematic diagram showing contaminating particles on a reticle assembly are illustrated. As shown in FIG. 1, a reticle assembly 100 includes a reticle 110 and a pellicle 120 covering the reticle 110. The reticle 110 has a quartz layer 111 and a chromium layer 112 coated on one side of the quartz layer 111. The pellicle 120 is configured to cover the chromium layer 112 of the reticle. The chromium layer 112 having gaps and lines forms a pattern for transferring an image to a wafer. Particle P1 is located on the other side of the quartz layer 111. Particle P2 is located in a gap of the chromium layer 112. Particle P3 is located on a surface of the chromium layer 112. Particle P4 is in a space between the chromium layer 112 and the pellicle 120. Particle P5 is located on a bottom surface of the pellicle 120. The particle P1 has minor impact on the quality of the semiconductor device, and can be removed by N2 blowing. The particle P2 has critical impact on the semiconductor quality, and must be removed by reticle cleaning processes with cleaning agents. The particle P3 usually has no impact on the semiconductor quality, and can be removed during the reticle cleaning processes. The particle P4 has minor impact on the semiconductor quality, and also can be removed during the reticle cleaning processes. The particle P5 usually has no impact on the semiconductor quality, and can be removed by N2 blowing.

One type of contaminating particles is referred as haze particles. Haze particles are precipitants formed from chemical residuals or impurities of the reticle cleaning processes.

For example, as illustrated in FIG. 2, when a solution including ammonium (NH₄⁺) and sulfate (SO₄²⁻) is used to clean the reticle assembly 100, the ammonium (NH₄⁺) and sulfate (SO₄²⁻) residuals may form ammonium sulfate (NH₄)₂SO₄ precipitants when exposed to short wavelength UV light, such as 248 nm or 193 nm light. Other precipitants such as organic compounds may also form during the photolithographic processes. The chemical residuals and impurities may be removed by N₂ purging. N₂ purging involves a process of introducing N₂ gas into a reticle stocker (or photomask stocker) and diffusing chemical residuals and impurities out of the reticle stocker. However, N₂ purging is unable to remove the chemical residuals or impurities (such as ammonium and sulfate) that are trapped in the space between the reticle 110 and the pellicle 120.

Accordingly, there remains a need to provide an apparatus that can prevent haze particles from contaminating the reticle.

### SUMMARY

In view of above, the present disclosure is directed to a reticle stage and an exposure apparatus having an electrostatic generator that can prevent haze particles from contaminating the reticle.

An implementation of the present disclosure is directed to a reticle stage for holding a reticle assembly. The reticle assembly has a reticle and a pellicle covering the reticle. The reticle stage includes a reticle stage base, a reticle holder disposed on the reticle stage base and for holding the reticle assembly over the reticle stage base, and an electrostatic generator coupled to the reticle assembly. The electrostatic generator is configured to generate static electricity to the reticle assembly. The static electricity alternates between positive electricity and negative electricity.

Another implementation of the present disclosure is directed to an exposure apparatus for transferring a pattern of a reticle assembly onto a wafer. The exposure apparatus includes an illumination module configured to illuminate the reticle assembly with light from a light source, a reticle stage configured to hold the reticle assembly, a projection module configured to project the pattern of the reticle assembly onto the wafer, and a wafer stage configured to position the wafer. The reticle stage includes a reticle stage base, a reticle holder disposed on the reticle state base and for holding the reticle assembly over the reticle stage base, and an electrostatic generator coupled to the reticle assembly. The electrostatic generator is configured to generate static electricity to the reticle assembly. The static electricity alternates between positive electricity and negative electricity.

Yet another implementation of the present disclosure is directed to a method of holding a reticle assembly during an exposure process to transfer a pattern of the reticle assembly onto a wafer. The reticle assembly has a reticle and a pellicle covering the reticle. As shown in FIG. 5, the method includes actions S501 to S503. In action S501, an exposure apparatus for transferring the pattern of the reticle assembly onto the wafer is provided. The exposure apparatus includes a reticle stage. The reticle stage includes a reticle stage base, a reticle holder disposed on the reticle stage base and for holding the reticle assembly over the reticle stage base, and an electrostatic generator coupled to the reticle holder. In action S502, the electrostatic generator generates static electricity to the reticle assembly. In action S503, the static electricity alternates between positive electricity and negative electricity.

As described above, the reticle stage and the exposure apparatus of the implementation of the present disclosure includes an electrostatic generator to generate static electricity to the reticle and the pellicle of the reticle assembly. The static electricity alternates between positive electricity and negative electricity at a predefined frequency to move charged particles trapped in the reticle assembly away from the surface of the reticle and the pellicle. Therefore, the reticle stage and the exposure apparatus of the implementations of the present disclosure can prevent haze particle formation on the surface of the reticle, and greatly reduce wafer defects caused by haze contamination.

### BRIEF DESCRIPTION OF THE DRAWINGS

Implementations of the present technology will now be described, by way of example only, with reference to the attached figures.

FIG. 1 is a schematic diagram showing contaminating particles on a reticle assembly in relative art.

FIG. 2 is a schematic diagram showing haze particles in the reticle assembly of FIG. 1.

FIG. 3A is a schematic diagram of an exposure apparatus according to an implementation of the present disclosure; FIG. 3B is a schematic diagram showing a cross-sectional view of a reticle stage of the exposure apparatus of FIG. 3A.

FIGS. 4A and 4B are schematic diagrams showing the effect of static electricity on a reticle assembly; FIG. 4C is a schematic diagram showing a charged particle distribution between a reticle and a pellicle of the reticle assembly of FIGS. 4A and 4B.

FIG. 5 is a flowchart of a method of holding a reticle assembly during an exposure process according to another implementation of the present disclosure.

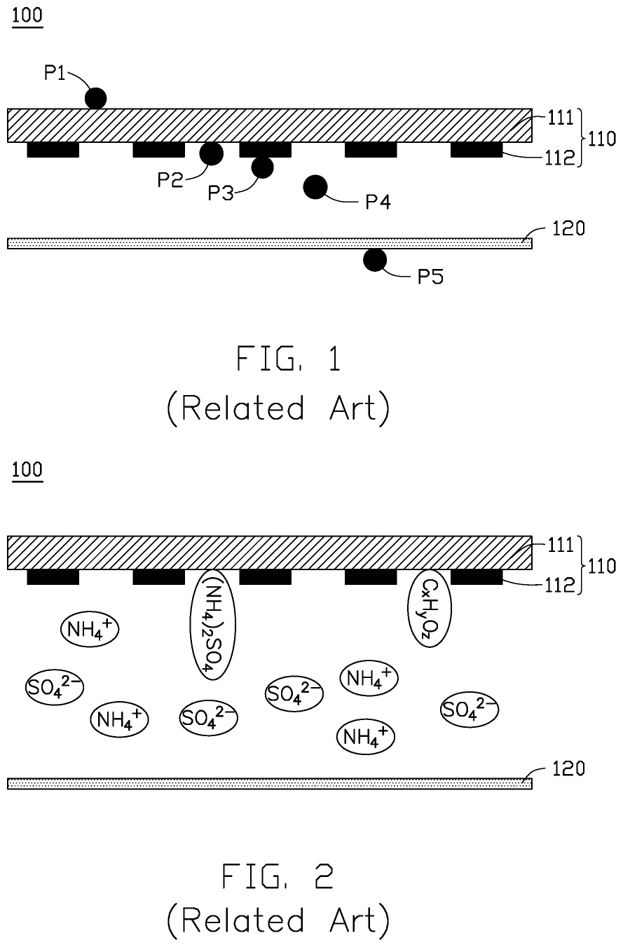

### DETAILED DESCRIPTION

The present disclosure will now be described more fully hereinafter with reference to the accompanying drawings, in which example implementations of the disclosure are shown. This disclosure may, however, be implemented in many different forms and should not be construed as limited to the example implementations set forth herein. Rather, these example implementations are provided so that this disclosure will be thorough and complete, and will fully convey the scope of the disclosure to those skilled in the art. Like reference numerals refer to like elements throughout.

The terminology used herein is for the purpose of describing particular example implementations only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, actions, operations, elements, and/or components, but do not preclude the presence or addition of one or more other features, regions, integers, actions, operations, elements, components, and/or groups thereof.

It will be understood that the term “and/or” includes any and all combinations of one or more of the associated listed items. It will also be understood that, although the terms first, second, third etc. may be used herein to describe various elements, components, regions, parts and/or sections, these elements, components, regions, parts and/or sections should not be limited by these terms. These terms are only used to distinguish one element, component, region, part or section from another element, component, region, layer or section. Thus, a first element, component, region, part or section discussed below could be termed a second element, component, region, layer or section without departing from the teachings of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

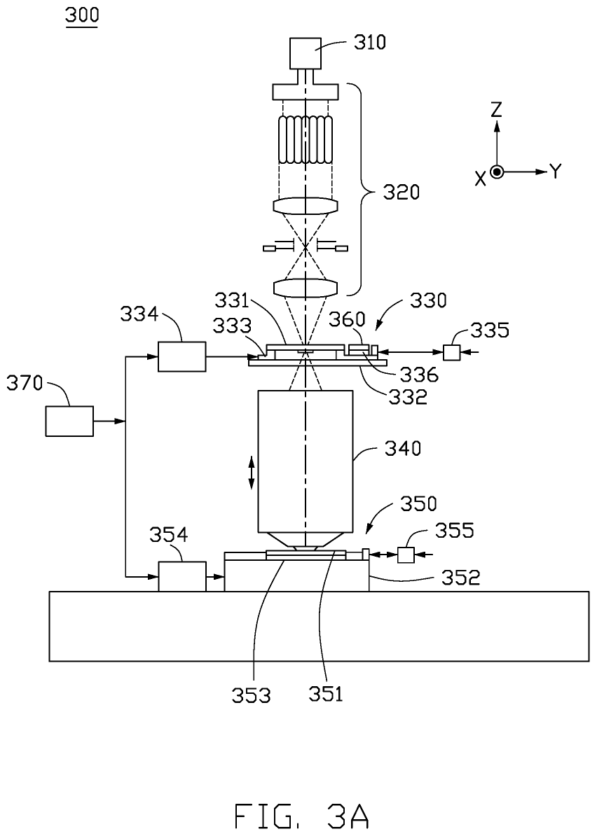

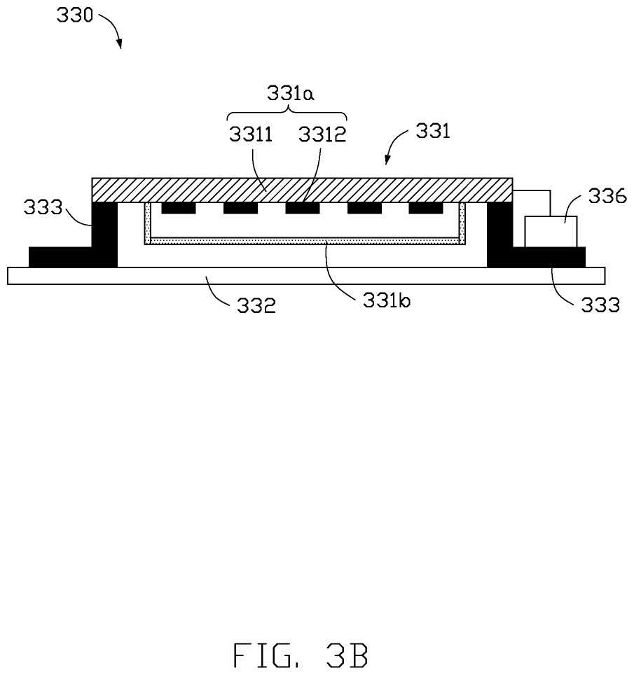

The description will be made as to the example implementations of the present disclosure in conjunction with the accompanying drawings in FIGS. 3A to 5. Reference will be made to the drawing figures to describe the present disclosure in detail, wherein depicted elements are not necessarily shown to scale and wherein like or similar elements are designated by same or similar reference numeral through the several views and same or similar terminology.

The present disclosure will be further described hereafter in combination with the accompanying figures.

Referring to FIG. 3A, a schematic diagram of an exposure apparatus 300 according to an implementation of the present disclosure is illustrated. The exposure apparatus 300 is a lithography apparatus for transferring a pattern of a reticle assembly 331 onto a wafer 351. The reticle assembly 331 includes a reticle and a pellicle covering the reticle. The exposure apparatus 300 includes an illumination module 320 for illuminating the reticle assembly 331 with light from a light source 310, a reticle stage 330 for positioning the reticle assembly 331, and a projection module 340 for projecting the pattern of the reticle assembly 331 onto the wafer 351. The exposure apparatus 300 also includes a wafer stage 350 for positioning the wafer 351, a determination unit 360, and a control unit 370.

The reticle stage 330 positions the reticle assembly 331 by moving the reticle assembly 331 in the Y-axis direction. In this implementation, the reticle stage 330 for holding the reticle assembly 331 includes a reticle stage base 332, a reticle holder 333 disposed on the reticle stage base 332 and for holding the reticle assembly 331 over the reticle stage base 332, and an electrostatic generator 336 coupled to the reticle assembly 331 to generate the static electricity to the reticle assembly 331. A first driving unit 334 drives the reticle stage base 332 according to a driving pattern. A first interferometer 335 continuously measures the position of the reticle stage base 332. The control unit 370 controls the first driving unit 334 to move the reticle stage base 332 according to the driving pattern at high accuracy.

The determination unit 360 determines a feature of the reticle assembly 331 placed on the reticle stage base 332. The determination unit 360 is constructed by, for example, a reading unit that reads an identifier such as a barcode formed on the reticle assembly 331. Also, the determination unit 360 may be constructed by an image sensing unit that senses the image of the reticle assembly 331, such as an area sensor, reflective sensor, or camera, and an image processing unit that processes an image sensed by the image sensing unit. The feature of the reticle assembly 331 includes, for example, at least one of the type of the reticle and the shape of the reticle. The type of the reticle varies. Examples are a general reticle (e.g., a reticle on which a circuit pattern is drawn) used to fabricate a semiconductor device, and a special reticle used for a special purpose. The special reticle may include various jigs and is not limited to the reticle on which a circuit pattern is formed.

The projection module 340 projects the pattern of the reticle assembly 331 illuminated by the light from the illumination module 320 at a predetermined magnification, such as ¼ or ⅕, onto the wafer 351. The projection module 340 may employ a first optical module solely including a plurality of lens elements, a second optical module including a plurality of lens elements and at least one concave minor (e.g., a catadioptric optical system), a third optical module including a plurality of lens elements and at least one diffractive optical element such as a kinoform, and a full minor module. Any necessary correction of the chromatic aberration may be performed by using a plurality of lens elements made from soda-lime glass materials having different dispersion values (or Abbe values), or arrange a diffractive optical element to disperses the light in a direction opposite to that of the lens elements.

The wafer stage 350 positions the wafer 351 by moving the wafer 351 in the X-axis and Y-axis directions. In this implementation, the wafer stage 350 includes a wafer stage base 352 on which the wafer 351 is placed, a wafer holder 353 for holding the wafer 351 on the wafer stage base 352, and a second driving unit 354 for driving the wafer stage base 352. A second interferometer 355 continuously measures the position of the wafer stage base 352. The control unit 370 controls the position of the wafer stage base 352 through the second driving unit 354 at high accuracy.

The control unit 370 includes a central processing unit (CPU) and a memory, and controls the overall operation of the exposure apparatus 300. The control unit 370 controls an exposure process of transferring the pattern of the reticle assembly 331 onto the wafer 351.

Referring to FIG. 3B, a schematic diagram of a cross-sectional view of the reticle stage 330 is illustrated. As shown in FIG. 3B, the reticle stage 330 of the present implementation includes the reticle stage base 332, the reticle holder 333 disposed on the reticle stage base 332 and for holding the reticle assembly 331 over the reticle stage base 332, and the electrostatic generator 336 coupled to the reticle assembly 331. The electrostatic generator 336 may be disposed on the reticle stage base 332. The electrostatic generator 336 is configured to generate static electricity to the reticle assembly 331. The static electricity alternates between positive electricity and negative electricity. Preferably, the static electricity alternates between positive electricity and negative electricity at a constant frequency ranging from 6 to 600 counts per minute. As shown in FIG. 3B, the reticle assembly 331 includes a reticle 331a and a pellicle 331b covering the reticle 331a. The reticle 331a includes a transparent layer 3311 and a metallic layer 3312 disposed on one side of the transparent layer 3311. The pellicle 331b covers the metallic layer 3312 of the reticle 331a. The transparent layer 3311 of the reticle 331a may be a quartz layer or a soda-lime glass layer. The metallic layer 3312 of the reticle 331a has gaps and lines to form the pattern for transferring an image to the wafer 351. Preferably, the metallic layer 3312 is a chromium layer. The reticle holder 333 is configured to hold the transparent layer 3311 of the reticle 331a.

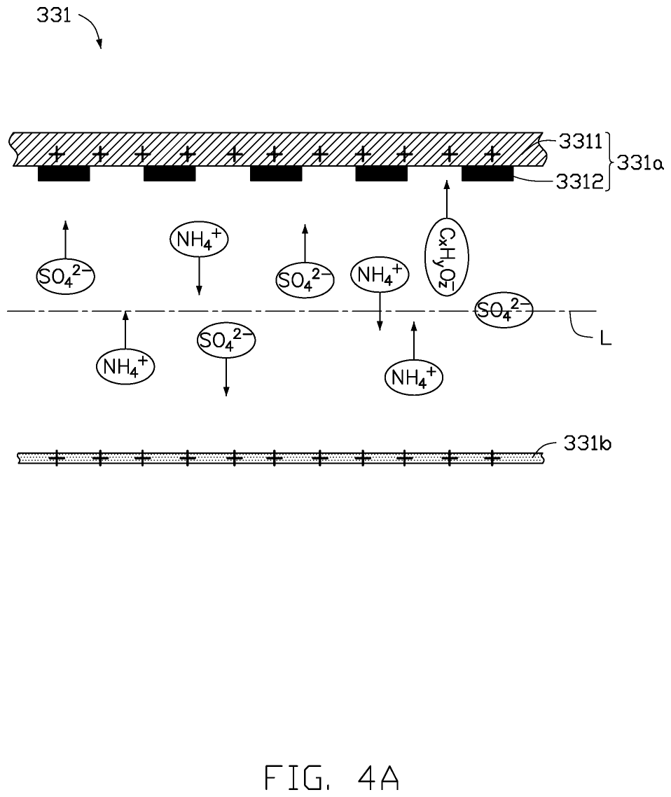

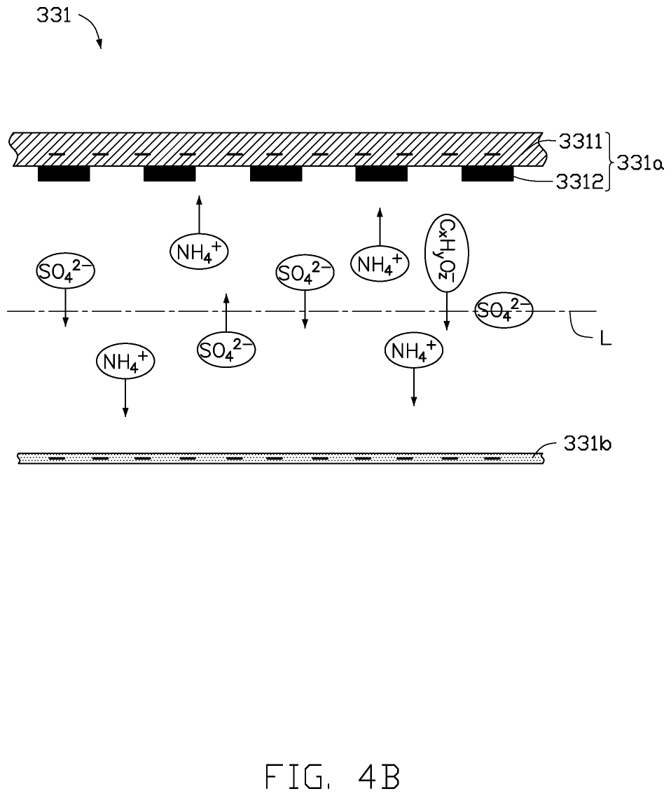

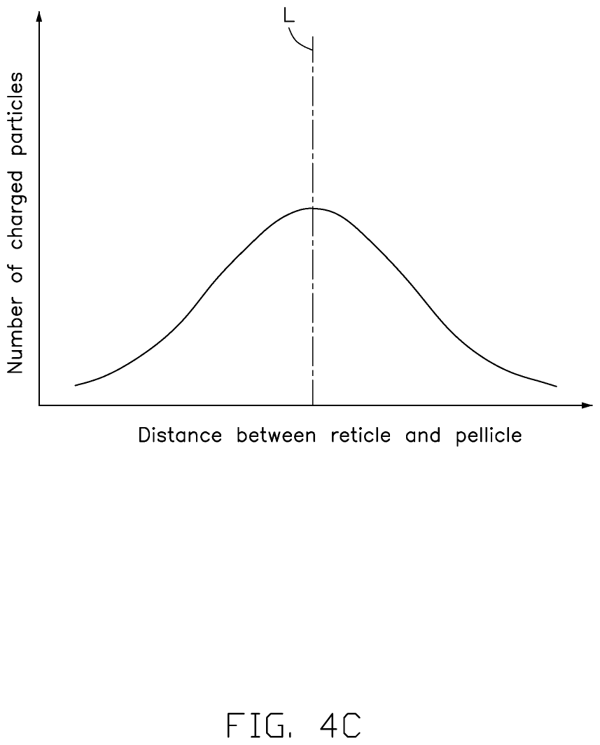

Referring to FIGS. 4A and 4B, schematic diagrams showing the effect of static electricity on the reticle assembly 331 of FIGS. 3A and 3B are illustrated. Charged particles such as ammonium (NH₄⁺), sulfate (SO₄²⁻) and other particles may be trapped in the space between the reticle 331a and the pellicle 331b after reticle cleaning processes. As the reticle assembly 331 is exposure to light, the charged particles may form haze contamination (caused by, for example, ammonium sulfate (NH₄)₂SO₄ precipitants) on the metallic layer 3312 of the reticle 331a, and cause critical defect on the wafer 351. The electrostatic generator 336 is configured to generate the static electricity to the reticle assembly 331. The static electricity alternates between positive electricity and negative electricity to prevent haze particles formation on the metallic layer 3312 of the reticle 331a. As show in FIG. 4A, when the electrostatic generator 336 generates positive static electricity to the reticle assembly 331, the reticle 331a and the pellicle 331b of the reticle assembly 331 carry positive static charges. Due to the repulsion force from the positive static charges carried by the reticle assembly 331, positively charged particles (such as NH₄⁺) near the surface of the reticle 331a and the surface of the pellicle 331b would move toward a center line L between the reticle 331a and the pellicle 331b. As shown in FIG. 4B, when the electrostatic generator 336 generates negative static electricity to the reticle assembly 331, the reticle 331a and the pellicle 331b carry negative static charges. Due to the repulsion force from the negative static charges carried by the reticle assembly 331, negatively charged particles (such as SO₄²⁻ or CₓH_{y}O_{z}⁻) near the surface of the reticle 331a and the surface of the pellicle 331b would move toward the center line L between the reticle 331a and the pellicle 331b. Therefore, by alternating the static electricity between positive electricity and negative electricity at a constant frequency, the charged particles tend to accumulate around the center line L of the space between the reticle 331a and the pellicle 331b. Referring to FIG. 4C, a schematic diagram showing the distribution of charged particles between the reticle 331a and the pellicle 331b of the reticle assembly 331 are illustrated. As shown in FIG. 4C, the number of charged particles around the center line L is much higher than those near the surface of the reticle 331a and the pellicle 331b. The charged particles are kept away from the surface of the reticle 331a and the pellicle 331b to prevent formation of haze particles on the surface of the metallic layer 3312 of the reticle 331. Therefore, defects on the wafer caused by haze particles during the exposure process can be greatly reduced.

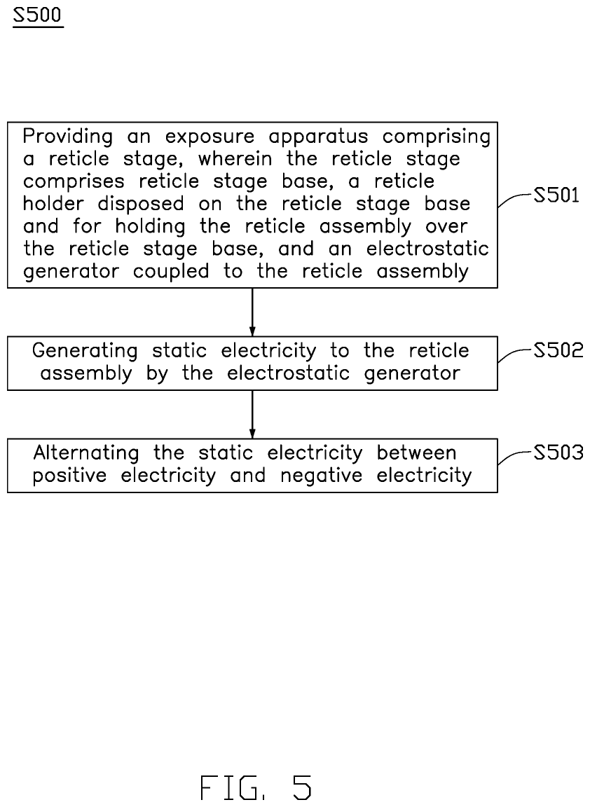

Referring to FIG. 5, a flowchart of a method of holding a reticle assembly during an exposure process to transfer a pattern of the reticle assembly onto a wafer according to another implementation of the present disclosure is illustrated. As shown in FIG. 5, the method S500 includes actions S501 to S503. The reticle assembly can be referred to the reticle assembly 331 of FIGS. 3A and 3B. The reticle assembly 331 includes a reticle 331a and a pellicle 331b covering the reticle 331a. In action S501, an exposure apparatus for transferring a pattern of the reticle assembly 331 onto a wafer is provided. The exposure apparatus can be referred to the exposure apparatus 300 of FIG. 3A. The exposure apparatus 300 includes a reticle stage 330. The reticle stage 330 includes a reticle stage base 332, a reticle holder 333 disposed on the reticle stage base 332 and for holding the reticle assembly 331 over the reticle stage base 332, and an electrostatic generator 336 coupled to the reticle assembly 331. In action S502, the electrostatic generator 336 generates static electricity to the reticle assembly 331. In action S503, the static electricity alternates between positive electricity and negative electricity. Preferably, the static electricity alternates between positive electricity and negative electricity at a frequency ranging from 6 to 600 counts per minute. The reticle 331a of the reticle assembly 331 includes a transparent layer 3311 and a metallic layer 3312 disposed on one side of the transparent layer 3311. The pellicle 331b covers the metallic layer 3312 of the reticle. The electrostatic generator 336 generates the static electricity to the reticle 331a and the pellicle 331b of the reticle assembly 331. The transparent layer 3311 of the reticle 331a is a quartz layer or a soda-lime glass layer. The metallic layer 3312 of the reticle 331a is a chromium layer having gaps and lines to form the pattern for transferring onto the wafer.

According to yet another implementation, the present disclosure is also directed to an exposure apparatus for transferring a pattern of a reticle assembly onto a wafer. The exposure apparatus and the reticle assemble can be respectively referred to the exposure apparatus 300 and the reticle assembly 331 of FIGS. 3A and 3B. As shown in FIGS. 3A and 3B, the exposure apparatus 300 includes an illumination module 320 configured to illuminate the reticle assembly 331 with light from a light source 310, a reticle stage 330 configured to hold the reticle assembly 331, a projection module 340 configured to project the pattern of the reticle assembly 331 onto the wafer 351, and a wafer stage 350 configured to position the wafer 351. The reticle stage 330 includes a reticle stage base 332, a reticle holder 333 disposed on the reticle stage base 332 and for holding the reticle assembly 331 over the reticle stage base 332, and an electrostatic generator 336 coupled to the reticle assembly 331. The electrostatic generator 336 is configured to generate static electricity to the reticle assembly 331. The static electricity alternates between positive electricity and negative electricity. Preferably, the static electricity alternates between positive electricity and negative electricity at a frequency ranging from 6 to 600 counts per minute. The reticle assembly 331 includes a reticle 331a and a pellicle 331b covering the reticle 331a. By periodically alternating the static electricity between positive electricity and negative electricity, charged particles such as ammonium (NH₄⁺), sulfate (SO₄²⁻) trapped between the space between the reticle 331a and the pellicle 331b tend to accumulated around a center line L of the space between the reticle 331a and the pellicle 331b, as shown in FIGS. 4A to 4C. The charged particles can be kept away from the surface of the reticle 331a and the pellicle 331b to prevent formation of haze particles on the surface of the reticle 331a. Therefore, defects on the wafer caused by haze particles during the exposure process can be greatly reduced.

The wafer stage 350 of the exposure apparatus 300 includes a wafer stage base 352, a wafer holder 353 disposed on the wafer stage base and for holding the wafer 351 over the wafer stage base 352. The exposure apparatus 300 may further include a first driving unit 334 coupled to the reticle stage base 332 and configured to drive the reticle stage base 332, a second driving unit 354 coupled to the wafer stage base 352 and configured to drive the wafer stage base 352, and a control unit 370 coupled to the first driving unit 334 and the second driving unit 354 to control a driving pattern of the first driving unit 334 and the second driving unit 354. The exposure apparatus 300 may further include a first interferometer 335 configured to measure a position of the retile stage base 332, and a second interferometer 355 configured to measure a position of the wafer stage base 352.

As described above, the reticle stage and the exposure apparatus of the implementations of the present disclosure include an electrostatic generator to generate static electricity to the reticle and the pellicle of the reticle assembly. The static electricity alternates between positive electricity and negative electricity at a constant frequency to move charged particles trapped in the reticle assembly away from the surface of the reticle and the pellicle. Therefore, the reticle stage and the exposure apparatus of the implementations of the present disclosure can prevent haze particle formation on the surface of the reticle, and greatly reduce wafer defects caused by haze contamination.

The implementations shown and described above are only examples. Many details are often found in the art such as the other features of a reticle stage and an exposure apparatus. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the implementations described above may be modified within the scope of the claims.

1. A reticle stage for holding a reticle assembly having a reticle and a pellicle covering the reticle, the reticle stage comprising:
a reticle stage base;
a reticle holder disposed on the reticle stage base and for holding the reticle assembly over the reticle stage base; and
an electrostatic generator coupled to the reticle assembly and configured to generate static electricity to the reticle assembly, and the static electricity alternates between positive electricity and negative electricity;
wherein the reticle of the reticle assembly comprises a transparent layer and a metallic layer disposed on one side of the transparent layer, and the pellicle covers the metallic layer of the reticle, the transparent layer of the reticle is a soda-lime glass layer.

2. The reticle state of claim 1, wherein the static electricity alternates at a constant frequency.

3. The reticle stage of claim 2, wherein the static electricity alternates at the frequency ranging from 6 to 600 counts per minute.

4-5. (canceled)

6. The reticle stage of claim 1, wherein the metallic layer of the reticle is a chromium layer.

7. The reticle stage of claim 1, wherein the reticle holder is configured to hold the transparent layer of the reticle.

8. An exposure apparatus for transferring a pattern of a reticle assembly onto a wafer, wherein the reticle assembly has a reticle and a pellicle covering the reticle, the exposure apparatus comprising:
an illumination module configured to illuminate the reticle assembly with light from a light source;
a reticle stage configured to hold the reticle assembly, the reticle stage comprising:
a reticle stage base;
a reticle holder disposed on the reticle stage base and for holding the reticle assembly over the reticle stage base; and
an electrostatic generator coupled to the reticle assembly and configured to generate static electricity to the reticle assembly, and the static electricity alternates between positive electricity and negative electricity;
wherein the reticle of the reticle assembly comprises a transparent layer and a metallic layer disposed on one side of the transparent layer, and the pellicle covers the metallic layer of the reticle, the transparent layer of the reticle is a soda-lime glass layer;
a projection module configured to project the pattern of the reticle assembly onto the wafer; and
a wafer stage configured to position the wafer.

9. The exposure apparatus of claim 8, wherein the static electricity alternates at a frequency ranging from 6 to 600 counts per minute.

10. (canceled)

11. The exposure apparatus of claim 8, wherein the metallic layer of the reticle is a chromium layer.

12. The exposure apparatus of claim 8, wherein the wafer stage comprises a wafer stage base, and a wafer holder disposed on the wafer stage base and for holding the wafer over the wafer stage base.

13. The exposure apparatus of claim 12, further comprising:
a first driving unit coupled to the reticle stage base and configured to drive the reticle stage base; and
a second driving unit coupled to the wafer stage base and configured to drive the wafer stage base.

14. The exposure apparatus of claim 12, further comprising:
a first interferometer configured to measure a position of the reticle stage base; and
a second interferometer configured to measure a position of the wafer stage base.

15. The exposure apparatus of claim 13, further comprising a control unit coupled to the first driving unit and the second driving unit and configured to control a driving pattern of the first driving unit and the second driving unit.

16. The exposure apparatus of claim 8, further comprising a determination unit configured to determine a feature of the reticle.

17. A method of holding a reticle assembly during an exposure process to transfer a pattern of the reticle assembly onto a wafer, wherein the reticle assembly has a reticle and a pellicle covering the reticle, the method comprising:
providing an exposure apparatus comprising a reticle stage, wherein the reticle stage comprises a reticle stage base, a reticle holder disposed on the reticle stage base and for holding the reticle assembly over the reticle stage base, and an electrostatic generator coupled to the reticle assembly, wherein the reticle of the reticle assembly comprises a transparent layer and a metallic layer disposed on one side of the transparent layer, and the pellicle covers the metallic layer of the reticle, the transparent layer of the reticle is a soda-lime glass layer;
generating static electricity to the reticle assembly by the electrostatic generator; and
alternating the static electricity between positive electricity and negative electricity.

18. The method of claim 17, wherein the static electricity alternates at a frequency ranging from 6 to 600 counts per minute.

19. (canceled)

20. The method of claim 17, wherein the metallic layer of the reticle is a chromium layer.
